(19) United States
(12) Patent Application Publication
(10) Pub. No.: US 2025/0163606 A1
(43) Pub. Date: May 22, 2025

(54) PRODUCTION METHOD FOR SINGLE CRYSTAL SEMICONDUCTOR FILM, PRODUCTION METHOD FOR MULTILAYER FILM OF SINGLE CRYSTAL SEMICONDUCTOR FILM, AND SEMICONDUCTOR ELEMENT

(71) Applicants: Mach Corporation Co., Ltd., Yokohama-city, Kanagawa (JP); National University Corporation Tokyo University of Agriculture and Technology, Fuchu-shi, Tokyo (JP); National Institute of Information and Communications Technology, Koganei-shi, Tokyo (JP); The University of Electro-Communications, Chofu-shi, Tokyo (JP)

(72) Inventors: Goubun AKATSUKA, Yokohama-city, Kanagawa (JP); Yoshiyuki SUDA, Fuchu-shi, Tokyo (JP); Nobumitsu HIROSE, Koganei-shi, Tokyo (JP); Satoshi TAMANYU, Toyama-shi, Toyama (JP); Yosuke AOYAGI, Yokohama-shi, Kanagawa (JP); Shota NOZAKI, Itabashi-ku, Tokyo (JP); Takahiro TSUKAMOTO, Chofu-shi, Tokyo (JP); Kento IKENO, Chofu-shi, Tokyo (JP); Hiroya ESAKI, Chofu-shi, Tokyo (JP)

(21) Appl. No.: 18/840,392

(22) PCT Filed: Feb. 23, 2023
(86) PCT No.: PCT/JP2023/006605

§ 371 Date: Aug. 21, 2024

(30) Foreign Application Priority Data
Feb. 24, 2022 (JP) 2022-027293

(51) Int. Cl. C30B 23/02; C30B 29/06; C30B 33/00; H01L 21/02; H01L 21/3205

(52) U.S. Cl. CPC C30B 23/02; C30B 29/06; C30B 33/00; C30B 33/005; H01L 21/02236; H01L 21/02247; H01L 21/02532; H01L 21/02579; H01L 21/02631; H01L 21/32051

(57) ABSTRACT

Since a high temperature process is required when adding impurities to a semiconductor crystal film by means of ion implantation or by means of thermal diffusion, it has been difficult to form a steep impurity profile. A production method for a single crystal semiconductor film by means of crystal growth using a magnetron sputtering device to which one or more group 14 semiconductor targets are attached, the method being characterized in that at least one of the targets is doped with impurities, the film-forming temperature is 300° C. or higher, the growth rate is 10 nm or less per minute, the sputtering gas is an inert gas, and the one or more targets are sputtered simultaneously.

### TECHNICAL FIELD

The present invention relates to a production method for a single crystal semiconductor film, a production method for a multilayer film of a single crystal semiconductor film, and a semiconductor element.

### BACKGROUND ART

In the production steps of semiconductors, one of the most important steps is an impurity doping step. A steep impurity profile and lowering the temperature of the steps have been demanded with the miniaturization of the element dimensions. As a means for impurity doping, techniques have been conventionally used, such as a thermal diffusion method, a chemical vapor deposition method (CVD method), and ion implantation followed by activation annealing.

In the CVD method, a substrate is usually heated to 600° C. or higher, and a raw material gas is decomposed on the substrate to form a film such as a Si layer. When the growth temperature is lower than 600° C., the decomposition efficiency of the source gas is reduced, the film-forming rate is significantly reduced, and hydrogen derived from the source gas remains in the film. On the other hand, when the growth temperature is raised, impurities are easily diffused, and the controllability of the impurity profile is low.

Non-patent Literature 1, for example, discloses a technique for growing a silicon (Si) crystal film doped with impurities by the CVD method using monosilane (SiH₄), disilane (Si₂H₆), phosphine (PH₃) or diborane (B₂H₆) as a source gas. It also describes that the growth temperature is 800 to 900° C. or higher.

In the ion implantation method, an appropriate mask can be provided on the substrate before implantation to restrict a region where impurities are implanted; however, the range thereof is a stochastic process of collision with a crystal lattice, and thus the impurity profile is the Gaussian distribution in principle. In addition, because the crystal is broken due to collision with the crystal lattice, crystal recovery annealing (activation annealing) generally at about 1000° C. is essential, which causes diffusion of impurities.

Non-Patent Literature 2, Non-patent Literature 3 and Non-patent Literature 4 disclose techniques on ion implantation and activation annealing. The temperature of activation annealing is 720 to 950° C. as an example, and in the activation annealing coupled with the ion implantation method, essentially a stochastic process, impurity diffusion is pointed out as a problem.

The thermal diffusion method is a thermal diffusion process, and thus the controllability of the impurity profile is low and the process temperature is also generally high, 800° C. or higher.

Another method for forming a semiconductor crystal film is a method for forming a film by sputtering (sputter epitaxy).

Patent Literature 1 (by the present inventor) discloses the sputter epitaxy method for forming a SiGe semiconductor thin film using Si and Ge targets. It describes that in order to form a doped semiconductor thin film, B, Al, Ga, In, N, P, Sb and the like as doping elements for the semiconductor may be contained in these targets, but does not disclose any specific growth conditions such as the growth temperature and the growth rate.

Patent Literature 2 (by the present inventors and others) describes that when a SiGe semiconductor layer is formed by the sputter epitaxy method, a dopant to provide conductivity for the laminated semiconductor film may be contained, and the growth temperature at this time is 350° C. or higher, but does not disclose any data to support that.

### CITATION LIST

### Patent Literature

Patent Literature 1: Japanese Unexamined Patent Application Publication No. 2006-100834
Patent Literature 2: WO2018/012546

### Non-Patent Literature

Non-patent Literature 1: VLSI & CVD, 1997, Maki Shoten
Non-patent Literature 2: Oyo-Buturi vol. 69, No. 4, page 427-434
Non-patent Literature 3: IEICE Technical Report SDM2015-71
Non-patent Literature 4: Journal of Applied Physics, vol 82, page 2228 (1997)

### SUMMARY OF INVENTION

### Technical Problem

In the methods described in Non-patent Literatures 1 to 4, conventional doping methods include a high temperature step, 700° C. or higher, and cannot cope with lowering the temperature of steps, which is demanded in the production steps of semiconductors that have been increasingly miniaturized. In the method described in Non-patent Literature 4, impurity diffusion is unavoidable in the high temperature step, which makes it difficult to secure a steep impurity profile. Furthermore, in the ion implantation step itself, essentially a stochastic process, there has been a problem in that impurity distribution expands before thermal diffusion.

The present inventors obtained findings that by discharge sputtering of one or two or more of targets obtained by doping a group 14 element such as silicon (Si) with boron (B) as impurities in an inert gas atmosphere using a magnetron sputtering device, and by using a target with a predetermined plane orientation, a boron-doped single crystal semiconductor film having a sufficient impurity activation rate at a lower temperature than that in the conventional methods was obtained on the Si substrate.

One of the objects according to some aspects of the present invention is to provide, in the production of an impurity-containing group 14 single crystal semiconductor film, a production method for a single crystal semiconductor film having a sufficient activation rate at a much lower temperature than that in the conventional methods and having a steep impurity profile, and a semiconductor device produced by the method.

### Solution to Problem

The present invention is a production method for a single crystal semiconductor film by means of crystal growth using a magnetron sputtering device to which an impurity-doped group 14 semiconductor target is attached, wherein the film-forming temperature is 300° C. or higher, and the growth rate is 10 nm or less per minute.

### Advantageous Effect of Invention

According to the production method of the present invention, it is possible to provide an impurity-containing group 14 semiconductor single crystal film having a sufficient activation rate at a low temperature.

### BRIEF DESCRIPTION OF DRAWING

FIG. 1 is the whole structure of a semiconductor crystal growth apparatus.

FIG. 2 is a process for forming a semiconductor crystal film.

FIG. 3 is a schematic cross-sectional structural diagram of a boron-doped semiconductor crystal film.

FIG. 4 is a graph showing a relationship between the growth temperature and activation rate of a semiconductor crystal film formed by crystal growth using boron-doped silicon targets with (100) and (111) plane orientation.

FIG. 5 is a graph showing the impurity profile of a silicon crystal film formed by crystal growth using a boron-doped silicon target with (100) plane orientation.

FIG. 6 is a schematic cross-sectional structural diagram of a group 15 element (phosphorus)-doped semiconductor crystal film.

FIG. 7A is a graph showing a relationship between the growth rate and impurity activation rate of a phosphorus-doped semiconductor crystal film.

FIG. 7B is a graph showing a relationship between the growth rate and impurity activation rate of a phosphorus-doped SiGe semiconductor crystal film.

FIG. 8A are graphs showing relationships between the growth temperature, carrier density and activation rate of silicon crystal films formed by crystal growth using a phosphorus-doped silicon target.

FIG. 8B is a graph showing a relationship between the growth temperature and carrier mobility of a silicon crystal film formed by crystal growth using a phosphorus-doped silicon target.

FIG. 9 are graphs showing the impurity (P) profiles of silicon crystal films (growth temperature 320° C., 400° C., 450° C., 500° C., 550° C., 600° C.).

FIG. 10 is a TEM photograph of grown films.

### DESCRIPTION OF EMBODIMENT

An embodiment of the present invention will now be illustrated as examples in detail using the drawings. It should be noted, however, that constituent elements described in this embodiment are shown as examples, and the scope of this invention is not limited only to those. In addition, all combinations of features illustrated in the embodiment are not essential for the solution of the invention.

### 1. Structure of a Semiconductor Crystal Film Growth Apparatus

### EMBODIMENT

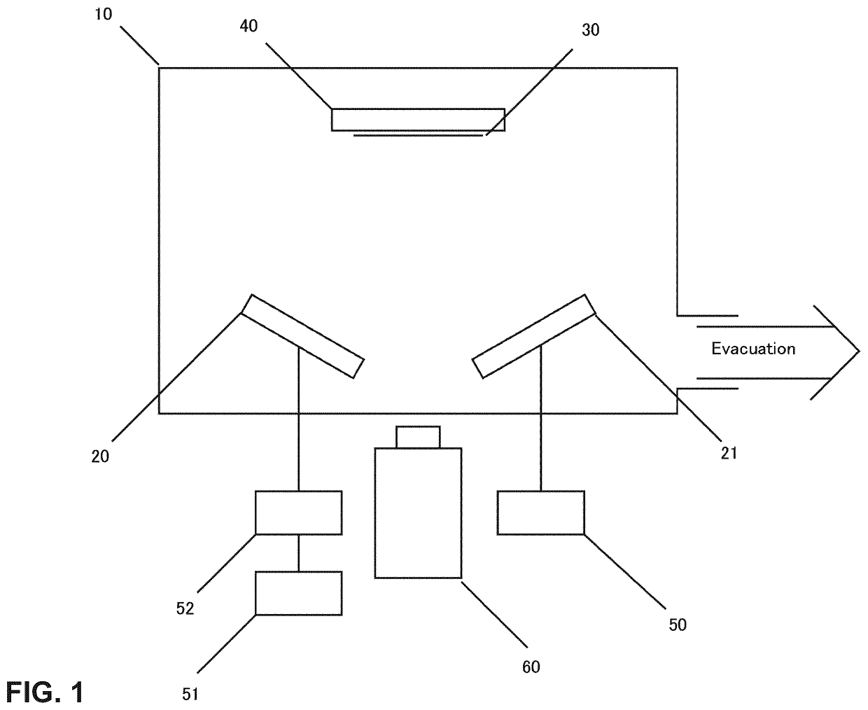

First, the structure of the semiconductor crystal film growth apparatus according to the present embodiment will be illustrated with reference to a drawing. FIG. 1 shows the whole structure of the growth apparatus. The apparatus includes a vacuum chamber 10, a target 20, a target 21, a Si substrate 30, a substrate mounting table with a heater 40, a DC power source 50, a high-frequency power source 51, a matching box 52 and a radiation thermometer 60.

The vacuum chamber 10 has an evacuation pump, not shown. The evacuation pump is desirably a contamination-free pump, for example, a turbomolecular pump, a sputter ion pump, a cryopump or a dry pump. The target 20 and target 21 are each any of a high purity group 14 element target or a group 15 element-doped group 14 element target or a boron-doped group 14 element target. The Si substrate 30 to grow a crystal is put on a place opposed to the target 20 and target 21. The target 20 and the target 21 can be put with the direction of the surface thereof inclined to the Si substrate 30. The mechanism to retain the inclined surfaces of the target 20 and the target 21 is achieved, for example, by a method for turning a flange to attach a target in the vacuum chamber 10 to a desired direction or an equivalent method.

The high-frequency power source 51 to apply a high-frequency voltage (e.g. a frequency of 13.56 MHz) is connected to the target 20 via the matching box 52, and the DC power source 50 to apply a DC voltage is connected to the target 21, respectively.

In the substrate mounting table with a heater 40, for example, the temperature of the substrate is measured by the radiation thermometer 60 provided outside the vacuum chamber, and the temperature is controlled so that the Si substrate 30 will have a predetermined temperature by control equipment (not shown).

This device is a magnetron sputtering device, in which magnets (not shown) are placed on the back of the target 20 and the target 21.

It should be noted that an embodiment having two targets is shown as an example in FIG. 1; however, the number of targets may be 3 or more or may be one. The target may be also a single crystal. The present embodiment has a structure having three single crystal targets or four single crystal targets. In addition, high-frequency voltage and DC voltage may be applied to each target switchably or both of them may be superimposed (and applied).

When simultaneously sputtering two or more of the same element targets, the targets may be placed symmetrically to the straight line passing through the center of the substrate to improve the uniformity of a grown film.

### 2. Process for Growing a Single Crystal Semiconductor Film

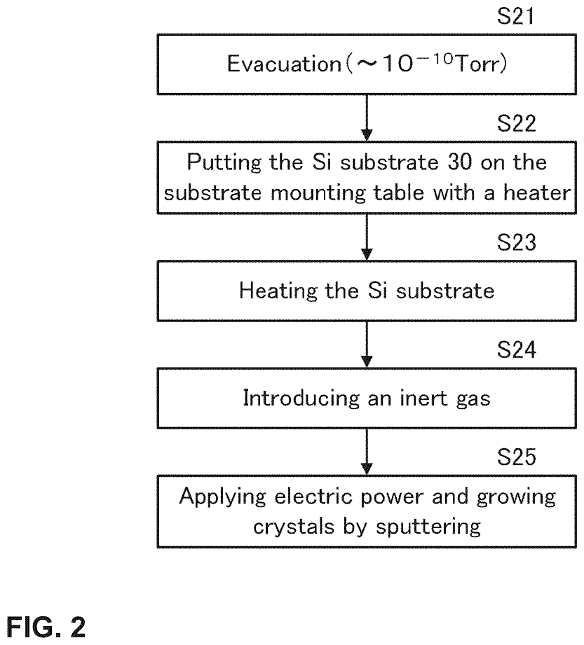

The process for growing a semiconductor crystal film according to the embodiment of the present invention will now be illustrated with reference to FIG. 2. It should be noted that each step in the process will be now represented as “S.”

First, the vacuum chamber 10 is evacuated to a very high vacuum (about 10⁻¹⁰ Torr) in S21.

In the subsequent S22, the Si substrate 30 is introduced on the substrate mounting table with a heater 40. It should be noted that the Si substrate 30 may be immersed in dilute hydrofluoric acid before being introduced to remove native oxide film.

Subsequently, the Si substrate 30 is heated by the substrate mounting table with a heater 40 in S23. At this time, the temperature of the substrate may be temporarily raised to a temperature higher than the growth temperature and reduced to the growth temperature after thermal cleaning.

Subsequently, an inert gas is introduced into the vacuum chamber 10 while adjusting the flow rate so that the growth pressure will be obtained in S24. It should be noted that the inert gas is argon (Ar) in the present embodiment; however, any inert gas may be used. The sputtering gas pressure of the vacuum chamber 10 is set to a value between 1.2 [mTorr] and 5 [mTorr] by adjusting the flow rate of the inert gas. In the present embodiment below, the pressure is set to 3 [mTorr] or 5 [mTorr].

In S25, subsequently, high-frequency electric power or DC voltage is applied to the target 20 or the target 21 or the target 20 and the target 21 simultaneously. The inert gas plasma was generated to sputter the target 20 or the target 21 or the target 20 and the target 21 simultaneously, which causes crystal growth on the Si substrate 30.

According to the above process, atoms contained in the target 20 and the target 21 are sputtered by ions from the inert gas plasma by applying DC voltage and high-frequency electric power in an inert gas atmosphere, which causes crystal growth on the Si substrate 30 opposed to the targets.

### 3. Examples of Single Crystal Semiconductor Film Growth

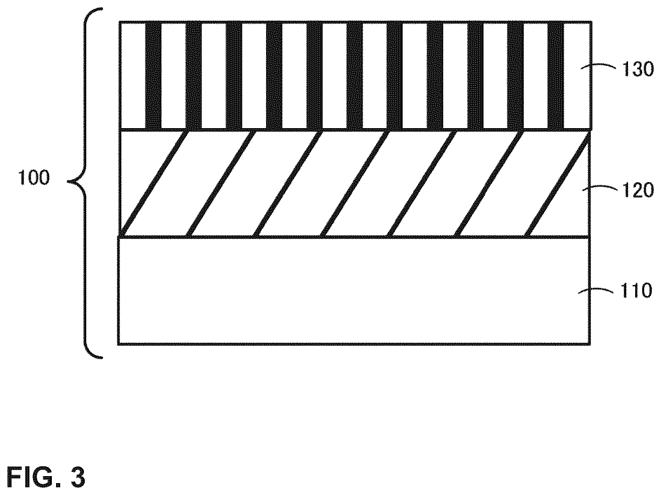

First, the semiconductor multilayer film according to the present embodiment will be illustrated with reference to a drawing. FIG. 3 is a cross-sectional diagram schematically showing the semiconductor crystal film 100 according to the present embodiment. The semiconductor crystal film 100 includes an N-type Si substrate 110, a Si crystal layer not containing impurities 120, and a boron-containing semiconductor crystal film 130.

In the present embodiment, a single crystal N-type Si substrate is used as the Si substrate 110; however, an SOI (Silicon on Insulator) substrate and an SOQ (Silicon on Quartz) substrate may be used, in which a single crystal Si thin film is formed on an insulator. The N-type Si substrate 110 may be e.g. a substrate with (100) plane orientation. In the present embodiment, the Si crystal layer not containing impurities 120 is provided on the N-type Si substrate 110 by the sputter epitaxy method; however, this Si layer not containing impurities may be also provided by other crystal growth methods such as the CVD method. Alternatively, Si and Ge mixed crystals may be provided by the sputter epitaxy method or other crystal growth methods. Si and C mixed crystals may be also grown.

### Dependency on Plane Orientation of Target

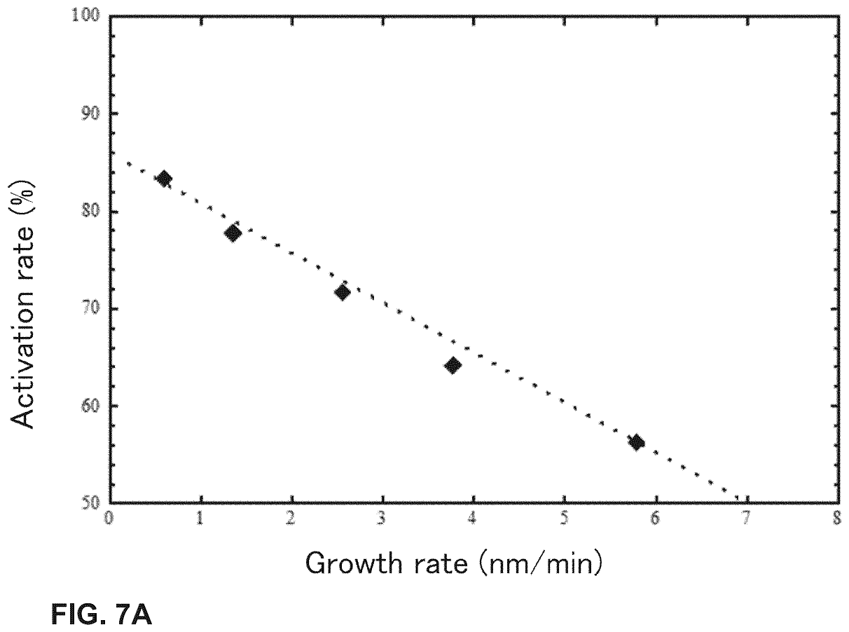

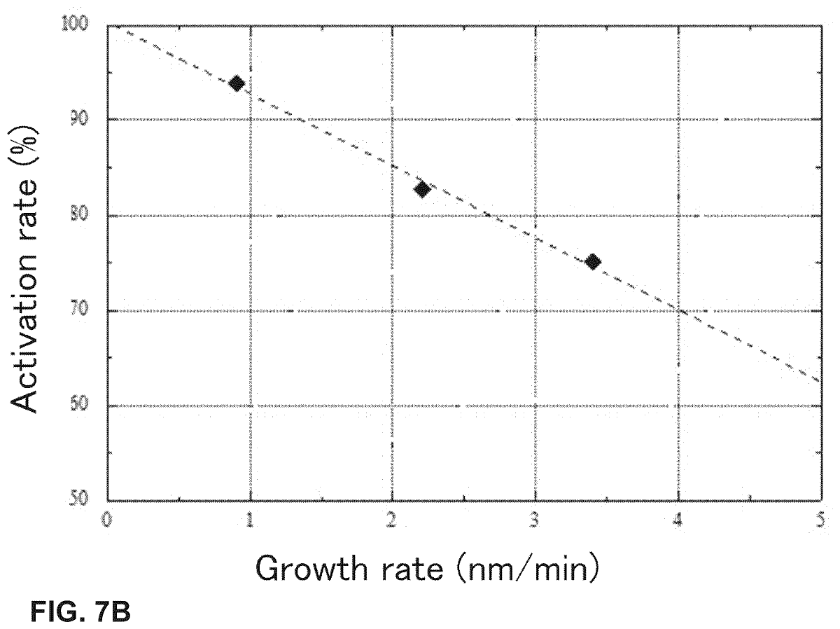

Using a target with (100) plane orientation (boron concentration 2.0×10¹⁹/cm³) and a target with (111) plane orientation (boron concentration 2.1×10¹⁹/cm³), which contain boron as impurities, the semiconductor layer 130 containing boron as impurities was grown. Ar was used as the inert gas, the pressure thereof was 3 [mTorr], and the growth rates of the Si crystal layer not containing impurities 120 and the boron-containing semiconductor crystal film 130 were both 5 nm per minute. When the growth rate is slower, the activation rate is further improved as shown in FIG. 7 below. It should be noted that the plane orientation tolerance of a target used is ±1° (JEITA). As long as the tolerance is about ±6° (tan 6°≈ 1/10), the crystal lattice condition on the outermost surface of a target does not have great differences, and the target can be used.

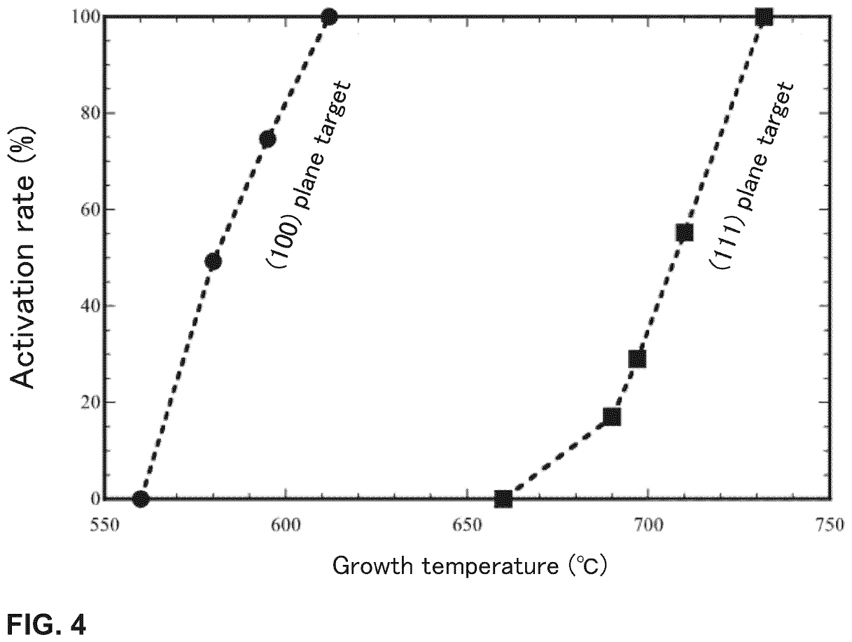

FIG. 4 shows differences in the impurity activation rate with respect to the growth temperature due to differences in plane orientation of targets. It is found that when using a target with (100) plane orientation, about 50% of impurities are activated at a growth temperature of 580° C. and 100% of impurities are activated at a growth temperature of 612° C., whereas when using a target with (111) plane orientation, the growth temperature is required to be 732° C. to reach an impurity activation rate of 100%.

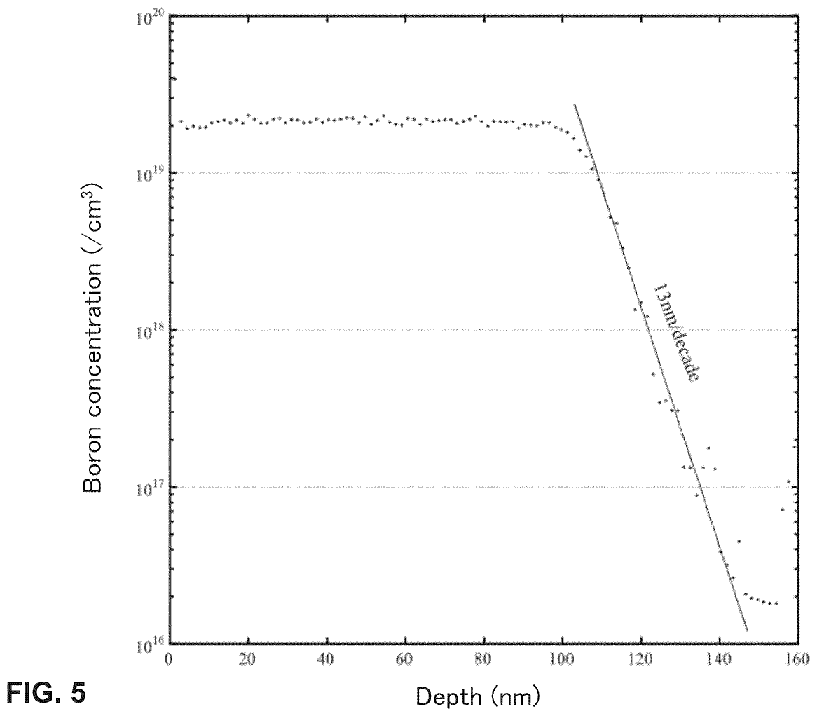

FIG. 5 shows the boron concentration in the depth direction when a target (100) containing boron as impurities is used and the growth (substrate) temperature is 580° C. The slope from a depth of around 100 nm of the graph is 13 [nm/decade]. This shows a depth at which the boron concentration is reduced to one tenth. This slope of the boron concentration in the depth direction is about one third of the value in Non-patent Literature 4, and it is found that a steep impurity profile can be formed.

The group 15 element-doped semiconductor crystal multilayer film according to the present embodiment will be illustrated with reference to a drawing.

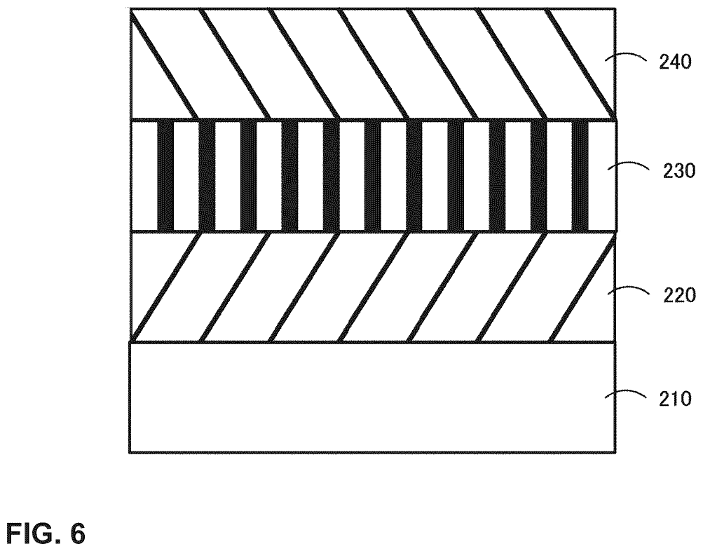

FIG. 6 is a cross-sectional diagram schematically showing the semiconductor crystal film 200 according to the present embodiment. The semiconductor crystal multilayer film includes a Si substrate 210, a Si crystal layer not containing impurities 220, a semiconductor crystal film containing a group 15 element as impurities 230, and a Si crystal layer not containing impurities 240.

The Si substrate 210 may be also a single crystal Si substrate. The Si substrate 210 may be also an SOI (Silicon on Insulator) substrate and an SOQ (Silicon on Quartz) substrate, in which a single crystal Si thin film is formed on an insulator. The Si substrate 210 may be also e.g. a Si substrate with (100) plane orientation.

In the present example, the Si crystal layer not containing impurities 220 is provided on the Si substrate 210 by the sputter epitaxy method; however, the same Si crystal layer or Si and Ge mixed crystals may be also provided by other methods such as the CVD method.

The group 15 element-containing Si crystal film 230 is provided on the Si crystal layer not containing impurities 220. It should be noted that phosphorus (P) is used as the group 15 element in the present embodiment below; however, any group 15 element may be used.

The Si crystal layer not containing impurities 240 is provided on the group 15 element-containing Si crystal film 230. In the present embodiment, the Si crystal layer not containing impurities 240 is grown by the sputter epitaxy method; however, the same Si crystal layer may be also provided by other methods such as the CVD method, and in the semiconductor crystal multilayer film, all crystal layers are grown at the same temperature, including the Si substrate 210, the Si crystal layer not containing impurities 220, the semiconductor crystal film containing a group 15 element as impurities 230, and the Si crystal layer not containing impurities 240.

In the present embodiment, a phosphorus (P)-doped Si crystal film was grown using a target including phosphorus (P) as impurities (100 plane orientation, phosphorus concentration 6×10¹⁹/cm³) by the sputter epitaxy method. Ar was used as the inert gas and the pressure thereof was 5 [mTorr].

### Impurity Activation Rate-Growth Rate

Changes in the impurity activation rate with respect to the crystal growth rate will now be illustrated. FIG. 7A represents the activation rate of impurities in the crystal film at a growth temperature of 400° C. when the growth rate of the semiconductor crystal film is changed.

As can be seen from the graph, as the growth rate is raised, the impurity activation rate is linearly reduced. As specific values, an activation rate of 72% at a growth rate of 2.7 nm per minute (growth rate of 20 atomic layers per minute), and an activation rate of 81% at a growth rate of 0.66 nm per minute (growth rate of 5 atomic layers per minute) are obtained. It is therefore found that a slower growth rate indicates a higher impurity activation rate. It was found that a semiconductor crystal film having an impurity activation rate of above 72% could be formed when the growth rate of the semiconductor crystal film was 2.7 nm or less per minute, and a semiconductor crystal film having an impurity activation rate of above 50% could be formed when the growth rate was 7 nm or less per minute at a growth temperature of 400° C.

FIG. 7B shows the activation rate of impurities in a crystal film when a phosphorus-doped SiGe growth rate is changed. The activation rate was 94% at a growth rate of 3.5 nm per minute and the activation rate was 100% at a growth rate of 0.9 nm per minute, and the same tendency as of the phosphorus-doped Si crystal film was obtained.

### Carrier Density and Impurity Activation Rate-Growth Temperature

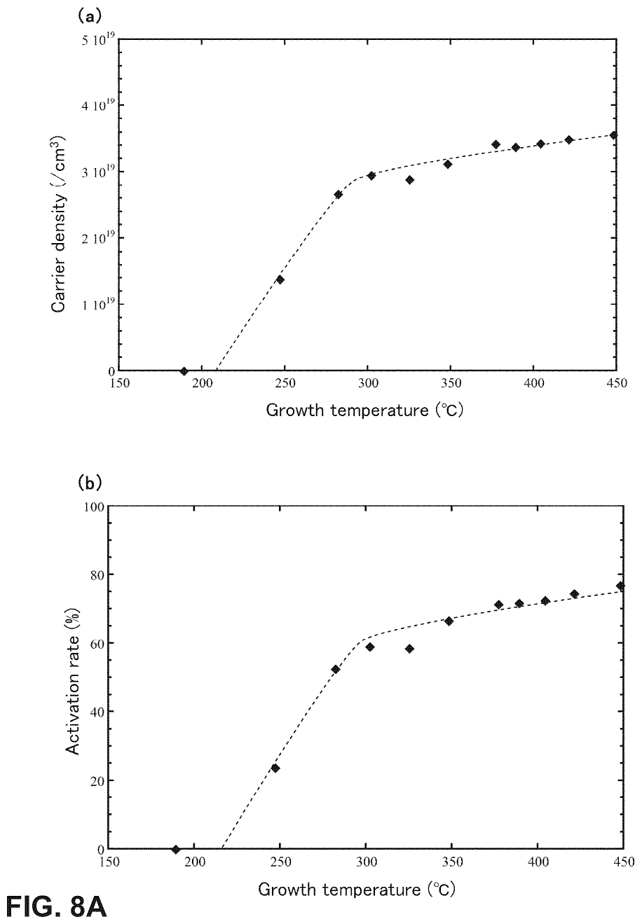

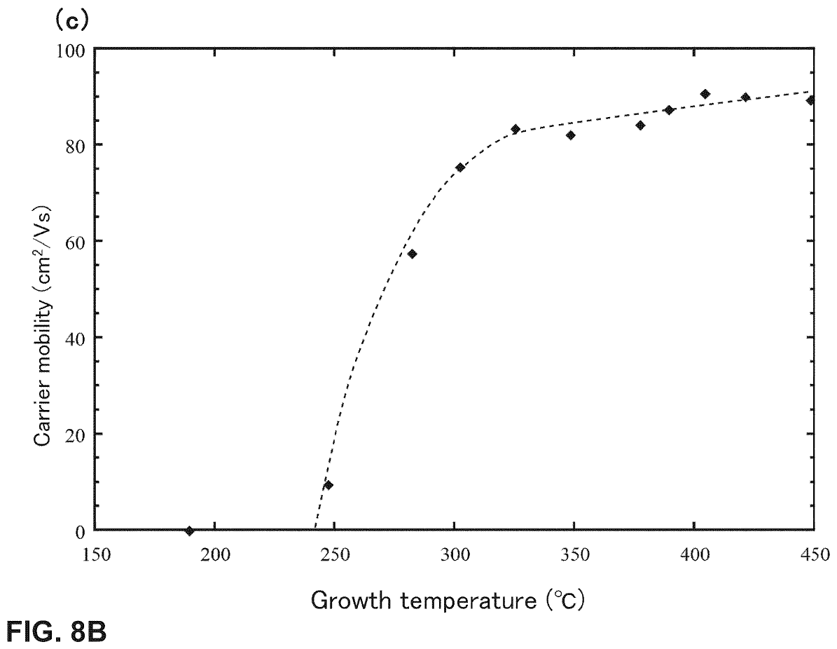

FIG. 8A(a) and FIG. 8A(b) show a relationship between the growth temperature and the carrier density, and a relationship between the growth temperature and the impurity activation rate, respectively. The growth rate was 2.7 nm per minute. Even when the growth temperature is raised, the impurity concentration in the semiconductor crystal film 230 is only slightly reduced, and thus the carrier density and the impurity activation rate show almost the same changes. When the growth temperature is lower than 250° C., the carrier density and the impurity activation rate are reduced. The carrier density and the impurity activation rate are moderately increased at a growth temperature from 300° C. to 450° C., and they are almost constant at 450° C. or higher. Specifically, the carrier density is 3×10¹⁹/cm³ and the activation rate is 59% at a growth temperature of 300° C., and it is found that a sufficiently high-quality crystal film is obtained. In addition, when the growth temperature is further raised, the carrier density and the activation rate are further increased, and a carrier density of 3.6×10¹⁹/cm³ and an activation rate of 75% are obtained at a growth temperature of 448° C.

### Carrier Mobility-Growth Temperature

FIG. 8B shows a relationship between the growth temperature and the carrier mobility. The growth rate was 2.7 nm per minute as with the above. The carrier mobility is low at lower than 250° C. In addition, the rate of increase in carrier mobility is reduced at a growth temperature of 300° C. or higher, and the mobility is almost constant at 400° C. or higher. This electron mobility is almost coincident with the universal mobility, and it is found that a high-quality semiconductor crystal film is obtained at a temperature higher than 400° C. This tendency is the same as of the impurity activation rate described above.

From FIGS. 8A(a) and (b) and FIG. 8B(c), it is found that an impurity-containing Si semiconductor crystal film having sufficient mobility for semiconductor device operation can be grown by the sputter epitaxy method at a growth temperature of at least 300° C. or higher and desirably 400° C. or higher.

### Impurity Profile-Growth Temperature

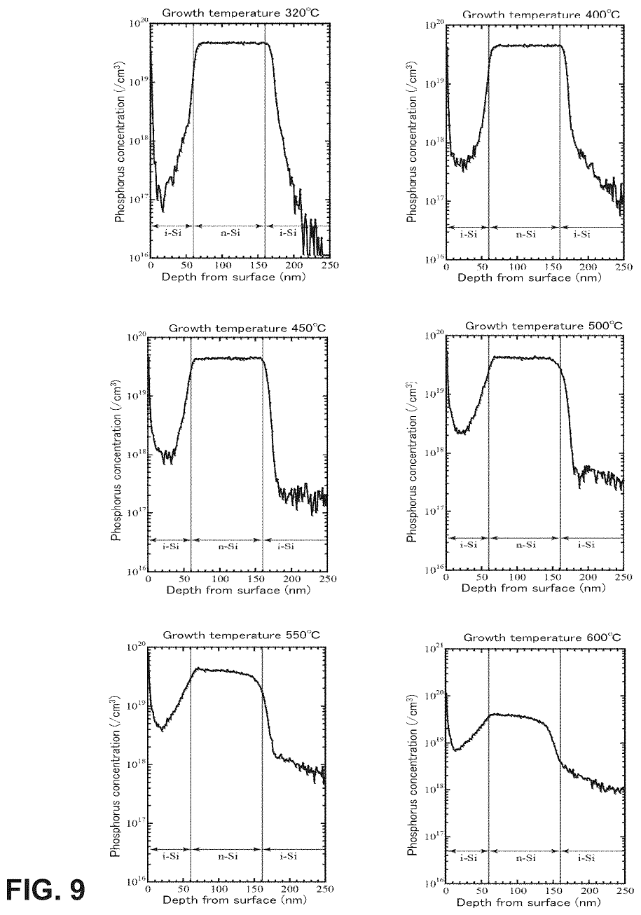

Next, when a phosphorus-doped Si crystal film was grown on a non-doped Si crystal film by the sputter epitaxy method, the degree of diffusion of doped impurities was measured. FIG. 9 show the phosphorus concentration in the depth direction when a target containing phosphorus as impurities was used and the growth temperature was 320° C., 400° C., 450° C., 500° C., 550° C. and 600° C. The growth rate was 2.7 nm per minute as with the above. In samples grown at 320° C. and 400° C., the slope at a depth of around 175 [nm] of the graphs is 10 [nm/decade]. In samples grown at a growth temperature 450° C. and a growth temperature of 500° C., the diffusion is slightly increased, 12 [nm/decade]; however, it is found that a steeper impurity profile than the profile in boron doping shown in FIG. 5 can be formed. The features of the impurity profile are shown in Table 1 as numerical values.

TABLE 1

| Growth temperature | Backward diffusion | Forward diffusion |
|---|---|---|
| (° C.) | (nm/decade) | (/cm³) |
| 320 | 10 | 1.8 × 10¹⁷ |
| 400 | 10 | 4.8 × 10¹⁷ |
| 450 | 12 | 1.0 × 10¹⁸ |
| 500 | 12 | 2.3 × 10¹⁸ |
| 550 | 44 | 4.9 × 10¹⁸ |
| 600 | 176 | 7.2 × 10¹⁸ |

In the table above, the backward diffusion represents a depth at which the concentration of impurities, which are reduced and diffused in an exponential manner in the depth direction from the semiconductor crystal film 230 containing group 15 impurities into the semiconductor layer 220 grown using a target not containing impurities, is reduced to 1/10. The forward diffusion represents the average value of concentrations of impurities, which are diffused from the semiconductor crystal film 230 containing group 15 impurities into the semiconductor layer 240 grown using a target not containing impurities, in an approximately constant impurity concentration part in a depth of about 15 nm to 35 nm. As can be seen with reference to the table 1 above, there is no diffusion into the non-doped semiconductor crystal film, a base of the impurity-doped semiconductor crystal film, at a growth temperature of lower than 600° C. and more desirably 500° C. or lower.

On the other hand, it is found that when the non-doped Si semiconductor crystal film is grown on the impurity-doped semiconductor crystal film at a growth temperature of 320 to 600° C., forward diffusion into the non-doped Si semiconductor crystal film is less at a lower temperature.

From the above experimental results, it is found that when a phosphorus (P)-doped semiconductor crystal film is grown by the sputter epitaxy method, the growth temperature is preferably 320 to 500° C.

### Smoothness of a Grown Film

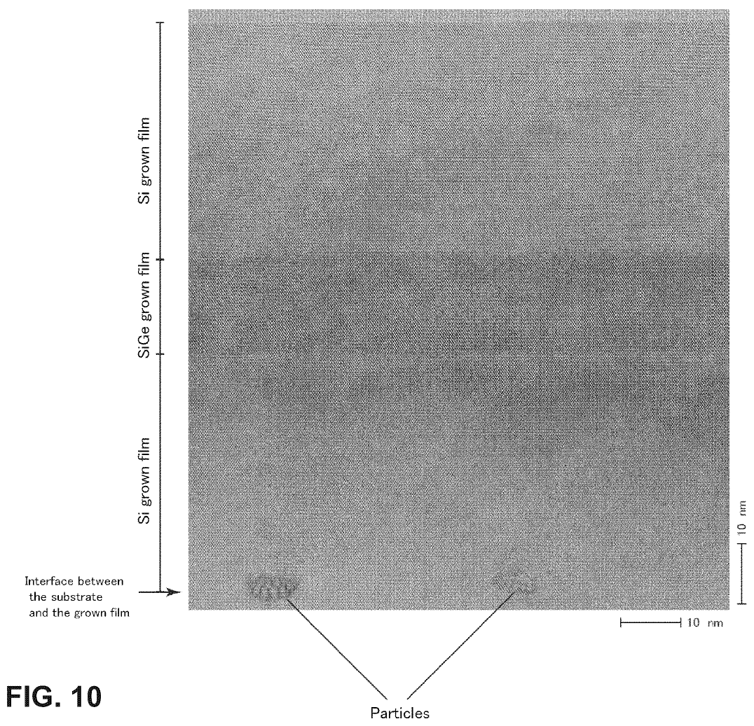

FIG. 10 is an example of cross-sectional TEM (Transmission Electron Microscopy) photographs of the grown films. Although particles, which usually hinder crystal growth, exist in the interface between the Si substrate and the Si grown layer shown in the photograph, when the Si crystal layer is grown to 30 nm, the upper surface thereof is smooth at an atomic layer level. Even after growth of a desired semiconductor multilayer film is completed, the surface thereof can be maintained to very clean conditions by retaining the semiconductor multilayer film in a very high vacuum, which is favorable, for example, to form a SiO₂ film by oxidation and to form an ohmic electrode by forming a film of metal such as titanium, nickel or tungsten or a multilayer film thereof in the subsequent process.

### (Other Examples)

Using an intrinsic semiconductor not containing impurities as a Si target or a Ge target, an intrinsic semiconductor crystal film of Si or SiGe can be grown in the same manner. Using the crystal growth method which can laterally form the above steep impurity profile, a P-type semiconductor film, an N-type semiconductor film, and an I-type semiconductor film are formed, and various semiconductor junctions such as a PN junction and a PIN junction can be formed. When the I layer of the PIN junction is SiGe, the bandgap is narrower than the bandgap of Si depending on the composition ratio thereof, and thus a photodiode which can respond to a longer wavelength region can be produced.

In the production method for a semiconductor crystal film according to the present invention, a target doped to a concentration D₁ and a target not containing a dopant may be simultaneously sputtered. By adjusting the electric power applied to the two targets, the concentration of impurities in a grown crystal film can be controlled (provided that the concentration is equal to or lower than D₁).

In the production method for a semiconductor crystal film according to the present invention, a target doped to a concentration D₁, a target doped to a concentration D₂ and a target not containing a dopant may be simultaneously sputtered. By adjusting electric power applied to the three targets, the concentration of impurities in a grown crystal film can be controlled (provided that the concentration is equal to or lower than D₁ and D₂).

In addition, impurity elements contained in each of the target doped to the concentration D₁ and the target doped to the concentration D₂ may be the same or different.

### REFERENCE SIGN LIST

10 Vacuum chamber
20, 21 Target
30 Si substrate

1. A production method for a single crystal silicon semiconductor film by means of crystal growth using a magnetron sputtering device to which one or more targets containing a silicon crystal target doped with boron with a surface plane orientation of within (100) ±6 degrees are attached,
wherein
a sputtering gas is an inert gas, and
the one or more targets containing the silicon crystal target doped with baron are sputtered simultaneously.

2. (canceled)

3. The production method for a single crystal silicon semiconductor film according to claim 1,
wherein the inert gas is argon.

4. (canceled)

5. The production method for a single crystal silicon semiconductor film according to claim 1,
wherein the surface plane orientation of the silicon crystal target doped with boron is within (100) ±1 degrees.

6. The production method for a single crystal semiconductor film according to claim 1,
wherein a growth temperature is 560° C. or higher.

7. (canceled)

8. A production method for a single crystal silicon semiconductor film by means of crystal growth using a magnetron sputtering device to which one or more targets containing a phosphorus-doped silicon semiconductor targets are attached
wherein
a growth temperature is 320° or higher and lower than 500° C., and
a growth rate is 7 nm or less per minute,
a sputtering gas is an inert gas, and
the one or more targets containing the phosphorus-doped silicon semiconductor target are sputtered simultaneously.

9. A production method for a silicon-germanium mixed crystal semiconductor film by means of crystal growth using a magnetron sputtering device to which one or more targets containing a phosphorus-doped silicon and/or germanium semiconductor target are attached,
wherein a growth rate is 3.5 nm or less per minute.

10. (canceled)

11. (canceled)

12. A production method for a multilayer film of a semiconductor oxide and a semiconductor film, wherein without taking the single crystal semiconductor film formed by the production method according to claim 1 out of a vacuum chamber, a surface thereof is oxidized.

13. A production method for a multilayer film of a semiconductor nitride and a semiconductor film, wherein without taking the single crystal semiconductor film formed by the production method according to claim 1 out of a vacuum chamber, a surface thereof is nitrided.

14. A production method for a multilayer film of metal and a semiconductor film, wherein a metal film is formed without taking the semiconductor film formed by the production method according to claim 1 out of a vacuum chamber.

15. A semiconductor element produced using the production method according to claim 1.

16. A production method for a multilayer film of a semiconductor oxide and a semiconductor film, wherein without taking the single crystal semiconductor film formed by the production method according to claim 8 out of a vacuum chamber, a surface thereof is oxidized.

17. A production method for a multilayer film of a semiconductor nitride and a semiconductor film, wherein without taking the single crystal semiconductor film formed by the production method according to claim 8 out of a vacuum chamber, a surface thereof is nitrided.

18. A production method for a multilayer film of metal and a semiconductor film, wherein a metal film is formed without taking the semiconductor film formed by the production method according to claim 8 out of a vacuum chamber.

19. A semiconductor element produced using the production method according to claim 8.

20. A production method for a multilayer film of a semiconductor oxide and a semiconductor film, wherein without taking the single crystal semiconductor film formed by the production method according to claim 9 out of a vacuum chamber, a surface thereof is oxidized.

21. A production method for a multilayer film of a semiconductor nitride and a semiconductor film, wherein without taking the single crystal semiconductor film formed by the production method according to claim 9 of a vacuum chamber, a surface thereof is nitrided.

22. A production method for a multilayer film of metal and a semiconductor film, wherein a metal film is formed without taking the semiconductor film formed by the production method according to claim 9 out of a vacuum chamber.

23. A semiconductor element produced using the production method according to claim 9.
